(19) United States
(12) Patent Application Publication
(10) Pub. No.: US 2026/0122771 A1
(43) Pub. Date: Apr. 30, 2026

(54) PRINTED CIRCUIT BOARD

(71) Applicant: SAMSUNG ELECTRO-MECHANICS CO., LTD., Suwon-si (KR)

(72) Inventors: Sang Hyun HAN, Suwon-si (KR); Yong Wan JI, Suwon-si (KR); Dong Keun LEE, Suwon-si (KR)

(73) Assignee: SAMSUNG ELECTRO-MECHANICS CO., LTD., Suwon-si (KR)

(21) Appl. No.: 19/082,980

(22) Filed: Mar. 18, 2025

(30) Foreign Application Priority Data
Oct. 31, 2024 (KR) 10-2024-0152707

(51) Int. Cl. H05K 1/02; H05K 1/03; H05K 1/11; H05K 1/18

(52) U.S. Cl. CPC H05K 1/0271; H05K 1/0306; H05K 1/113; H05K 1/185; H05K 2201/09527; H05K 2201/096; H05K 2201/09609; H05K 2201/09618; H05K 2201/09827; H05K 2201/09981; H05K 2201/10424

(57) ABSTRACT

The present disclosure relates to a printed circuit board including: a glass layer; a cavity penetrating between an upper surface and a lower surface of the glass layer; a metal layer disposed on a wall surface of the cavity; and an electronic component at least partially disposed in the cavity and spaced apart from the metal layer, and an upper surface of the metal layer is disposed on substantially the same level as the upper surface of the glass layer, or is disposed below the upper surface of the glass layer, and a lower surface of the metal layer is disposed on substantially the same level as the lower surface of the glass layer, or is disposed above the lower surface of the glass layer.

### CROSS-REFERENCE TO RELATED APPLICATION(S)

This application claims benefit of priority to Korean Patent Application No. 10-2024-0152707 filed on Oct. 31, 2024, in the Korean Intellectual Property Office, the disclosure of which is incorporated herein by reference in its entirety.

### TECHNICAL FIELD

The present disclosure relates to a printed circuit board.

### BACKGROUND

As the era of artificial intelligence (AI) semiconductors begins, developments related to glass substrates are actively underway. For example, semiconductor package substrates formed of plastic materials may face various limitations as micro-processing is required during a packaging process. For example, it may be difficult to reduce a thickness of a plastic substrate, and the substrate may warp. Accordingly, a glass substrate may be used as a solution to this problem. However, in the case of the glass substrate, cracks may occur due to the occurrence of impacts on a side area of the glass when mounting chips after cavity processing. Additionally, cracks may occur in the glass substrate due to stress generated when the build-up process is performed on the glass substrate.

### SUMMARY

An aspect of the present disclosure is to provide a printed circuit board capable of preventing cracks from occurring when an electronic component is disposed on a glass layer having a cavity formed thereon.

Another aspect of the present disclosure is to provide a printed circuit board capable of preventing cracks from occurring in a glass layer when forming a build-up layer on the glass layer.

One of the various solutions of the present disclosure is to preserve a metal layer formed by plating on a wall area of a cavity formed in a glass layer, thereby preventing microcracks that may occur due to collision during an embedding process of an electronic component, and to reduce tensile stress of the glass layer therethrough, thereby reducing horizontal cracks in the glass layer that may occur during the build-up process.

For example, a printed circuit board according to an example embodiment may include: a glass layer; a cavity penetrating between an upper surface and a lower surface of the glass layer; a metal layer disposed on a wall surface of the cavity; and an electronic component at least partially disposed in the cavity and spaced apart from the metal layer, and an upper surface of the metal layer may be disposed on substantially the same level as the upper surface of the glass layer or may be disposed below the upper surface of the glass layer, and a lower surface of the metal layer may be disposed on substantially the same level as the lower surface of the glass layer or may be disposed above the lower surface of the glass layer.

For example, a printed circuit board may include: a glass layer; a cavity penetrating through at least a portion of a space between an upper surface and a lower surface of the glass layer; a metal layer disposed on a wall surface of the cavity; and an electronic component at least partially disposed in the cavity and spaced apart from the metal layer, and the metal layer may include a first metal layer disposed on the wall surface of the cavity and a second metal layer disposed on the first metal layer, and the first metal layer may include a stack structure of a titanium layer and a copper layer, and the second metal layer may include a copper layer.

One of the various effects of the present disclosure is to provide a printed circuit board that may prevent cracks from occurring when an electronic component is disposed on a glass layer having a cavity formed therein.

Another of the various effects of the present disclosure is to provide a printed circuit board that may prevent cracks from occurring on a glass layer when forming a build-up layer on the glass layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a schematic cut plan view taken along line A-A′ of the printed circuit board of FIG. 2;

FIG. 4 is a cross-sectional view schematically illustrating another example of a printed circuit board;

FIG. 5 is a schematic cut plan view taken along line B-B′ of the printed circuit board of FIG. 4; and

FIG. 6 is process cross-sectional views schematically illustrating a process of forming a through-hole and a cavity in a glass layer, forming a metal via and a metal layer in the through-hole and on a wall surface of the cavity, and disposing an electronic component in the cavity formed on the metal layer.

### DETAILED DESCRIPTION

Hereinafter, the present disclosure will be described with reference to the accompanying drawings. In the drawings, the shape and size of the elements may be exaggerated or reduced for clearer description.

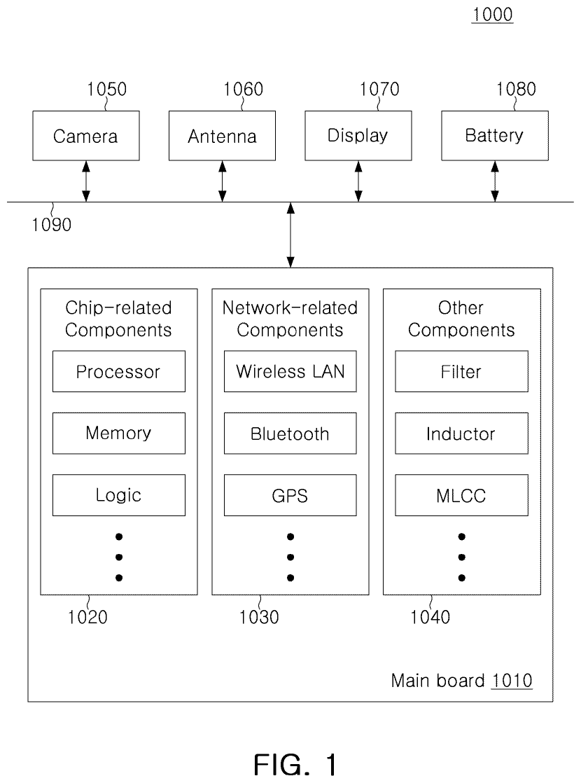

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component, and a server. However, the electronic device 1000 is not limited thereto, and may be any other electronic device that processes data in addition thereto.

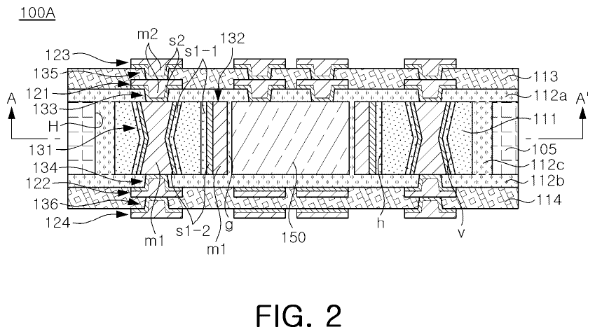

FIG. 2 is a cross-sectional view schematically illustrating an example of a printed circuit board.

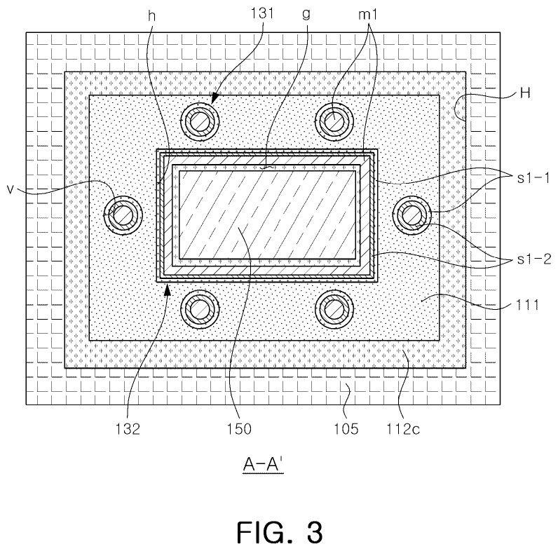

FIG. 3 is a schematic cut plan view taken along line A-A′ of the printed circuit board of FIG. 2.

Referring to the drawings, a printed circuit board 100A according to an example embodiment may include a glass layer 111, a through-hole v penetrating between an upper surface and a lower surface of the glass layer 111, a metal via 131 filling at least a portion of the through-hole v, a cavity h penetrating through at least a portion of an upper surface and a lower surface of the glass layer 111, a metal layer 132 disposed on a wall surface of the cavity h, and an electronic component 150 at least partially disposed in the cavity h and spaced apart from the metal layer 132.

In this case, upper surfaces of each of the metal via 131 and the metal layer 132 may be disposed on substantially the same level as the upper surface of the glass layer 111 or may be disposed below the upper surface of the glass layer 111. Additionally, lower surfaces of each of the metal via 131 and the metal layer 132 may be disposed on substantially the same level as the lower surface of the glass layer 111 or may be disposed above the upper surface of the glass layer 111. In an example, the upper surface and lower surface of the metal via 131 and the upper surface and lower surface of the metal layer 132 may be substantially coplanar with the upper surface and lower surface of the glass layer 111, respectively.

In this manner, in the printed circuit board 100A according to an example embodiment, the metal layer 132 may be disposed on a wall surface of the cavity h in which the electronic component 150 is disposed, and the metal layer 132 may not extend onto the upper surface and lower surface of the glass layer 111. In this case, damage that may occur when the glass layer 111 and the electronic component 150 collide during an embedding process of the electronic component 150 may be reduced by the metal layer 132, thus reducing cracks occurring on the wall surface of the glass layer 111. Additionally, tensile stress near the cavity h of the glass layer 111 may be reduced by the metal layer 132, and thus, cracks occurring on the glass layer 111 may be reduced when forming a build-up layer.

Meanwhile, the metal via 131 may include first metal layers s1-1 and s1-2 disposed on the wall surface of the through-hole v and a second metal layer m1 disposed on the first metal layers s1-1 and s1-2 to fill at least a portion of the through-hole v. Additionally, the metal layer 132 may include first metal layers s1-1 and s1-2 disposed on the wall surface of the cavity h and a second metal layer s1-2 disposed on the first metal layers s1-1 and s1-2. The first metal layers s1-1 and s1-2 may include a stack structure of the first seed layer s1-1 and the second seed layer s1-2. For example, the first seed layer s1-1 may include a titanium layer, and the second seed layer s1-2 may include a copper layer. Alternatively, the first seed layer s1-1 may include a stack structure of a titanium layer and a copper layer, and the second seed layer s1-2 may further include a copper layer. For example, the first metal layers s1-1 and s1-2 may be a seed layer formed by sputtering and/or electroless plating. Accordingly, the titanium layer may include sputtered titanium, and the copper layer may include sputtered copper, chemical copper, or combinations thereof. The second metal layer m1 may include a plating layer m1. For example, the plating layer m1 may include a copper layer. For example, the second metal layer m1 may be a plating layer formed by electrolytic plating. Accordingly, the copper layer may include electrolytic copper. For example, the metal layer 132 may be formed simultaneously when the metal via 131 is formed by a sputtering and/or plating process.

Meanwhile, in the metal layer 132, thicknesses of the first metal layers s1-1 and s1-2 may be greater than a thickness of the second metal layer m1 in a direction, substantially perpendicular to the wall surface of the cavity h. For example, the first metal layers s1-1 and s1-2 may be a seed layer formed by sputtering and/or electroless plating, and the second metal layer m1 may be a plating layer formed by electrolytic plating, so that the first metal layers s1-1 and s1-2 and the second metal layer m1 may have a significant thickness difference. From a similar perspective, in the case of the metal via 131, thicknesses of the first metal layers s1-1 and s1-2 may be greater than a thickness of the second metal layer m1 in a direction, substantially perpendicular to the wall surface of the through-hole v.

Meanwhile, the cavity h may be in a form of continuously surrounding a side surface of the electronic component 150. For example, the cavity h may have an approximately rectangular shape in a plane. Accordingly, the metal layer 132 may be disposed on the wall surface of the cavity h so as to continuously surround the side surface of the electronic component 150 in the form of a metal plate. In this case, the crack prevention effect as described above may be more excellent. The cavity h may be a through-cavity, but may also be a blind cavity if necessary.

Meanwhile, a printed circuit board 100A according to an example embodiment may further includes, if necessary, a frame 105 having a through-portion H in which at least a portion of a glass layer 111 is disposed, a first insulating layer 112a disposed on the upper surface of each of the frame 105 and the glass layer 111, a first wiring layer 121 disposed on an upper surface of the first insulating layer 112a, a first via layer 133 penetrating through the first insulating layer 112a and connecting the first wiring layer 121 to the metal via 131 and the electronic component 150, a second insulating layer 112b disposed on lower surfaces of each of the frame 105 and the glass layer 111, a second wiring layer 122 disposed on a lower surface of the second insulating layer 112b, a second via layer 134 penetrating through the second insulating layer 112b and connecting the second wiring layer 122 to the metal via 131, and a third insulating layer 112c filling at least a portion of a space g between the frame 105 and the glass layer 111 in the through-portion H.

In this manner, the printed circuit board 100A according to an example embodiment may further include a frame 105 having a through-portion H, through which a process warpage may be more easily controlled. Additionally, the frame 105 may be provided on a panel level, and in this case, a plurality of printed circuit board 100A units may be manufactured in a single process using the frame 105 as a jig, and a plurality of unit substrates may be obtained through a singulation process. Additionally, the frame 105 and the glass layer 111 may be surrounded through the first to third insulating layers 112a, 112b and 112c and the through-portion H may be filled, thereby achieving a stress relief effect. Additionally, the first and second wiring layers 121 and 122 may be formed on the first and second insulating layers 112a and 112b, thereby improving adhesion. Additionally, an electrical connection path may be provided in a substrate through the first and second via layers 133 and 134.

Meanwhile, connection vias connected to the metal vias 131 of each of the first and second via layers 133 and 134 may be in contact with the upper surface and the lower surface of the metal via 131. For example, the connection vias and the upper surface and the lower surface of the metal via 131 may be directly connected without a separate via land or a separate via pad. Accordingly, an overall thickness of the substrate may be reduced. Additionally, the process may be simplified. Additionally, it may be possible to minimize adverse effects such as delamination that may occur when a land is formed in the glass layer 111.

Meanwhile, the third insulating layer 112c may have an interlayer boundary with each of the first and second insulating layers 112a and 112b. For example, the third insulating layer 112c may include a filler, and may be formed separately from the first and second insulating layers 112a and 112b. However, the present disclosure is not limited thereto, and the third insulating layer 112c may be integrated with at least one of the first and second insulating layers 112a and 112b. For example, when stacking one or more of the first and second insulating layers 112a and 112b, a space excluding the electronic component 150 in the through-portion H may be filled, thereby forming the third insulating layer 112c. The integration may be one layer without boundaries.

Meanwhile, the printed circuit board 100A according to an example embodiment may further include, if necessary, a first build-up insulating layer 113 disposed on the upper surface of the first insulating layer 112a, a first build-up wiring layer 123 disposed on an upper surface of the first build-up insulating layer 113, a first build-up via layer 135 penetrating through the first build-up insulating layer 113 and connecting the first build-up insulating layer 113 and the first wiring layer 121, a second build-up insulating layer 114 disposed on the lower surface of the second insulating layer 112b, a second build-up wiring layer 124 disposed on a lower surface of the second build-up insulating layer 114, and a second build-up via layer 136 penetrating through the second build-up insulating layer 114 and connecting the second build-up wiring layer 124 and the second wiring layer 122.

In this manner, the printed circuit board 100A according to an example embodiment may have a multilayer substrate structure in which a build-up layer is further formed on an upper side and/or a lower side of the glass layer 111. For example, the printed circuit board 100A according to an example may be a package substrate on which a semiconductor chip is mounted. The package substrate may be a large-area substrate used for a server, or the like. Depending on need, the build-up layer may be further formed only on the upper side or the lower side of the glass layer 111, or the build-up layer may be further formed in an asymmetrical form on the upper side and the lower side thereof. For example, the printed circuit board 100A according to an example embodiment may be an interposer substrate having an asymmetrical structure.

Hereinafter, the components of the printed circuit board 100A according to an example embodiment will be described in more detail with reference to the drawings.

The frame 105 may include a material having excellent rigidity, for example, Copper Clad Laminate (CCL) or Unclad CCL, but the present disclosure is not limited thereto. For example, the frame 105 may include other organic materials having excellent rigidity, or may include other types of inorganic materials having excellent rigidity. The frame 105 may be used as a jig during a process, and therefore, the process may be performed on a panel level through the frame 105. Additionally, the frame 105 may remain in a final unit after singulation, which may be more advantageous for wedge control.

The glass layer 111 may include glass, which is an amorphous solid. The glass may include, for example, pure silicon dioxide (about 100% SiO₂), soda lime glass, borosilicate glass, and alumino-silicate glass. However, the present disclosure is not limited thereto, and alternative glass materials, such as fluorine glass, phosphate glass, and chalcogen glass, may also be used as materials of the glass layer 111. Additionally, other additives may be further included to form glass having specific physical properties. These additives may include not only calcium carbonate (e.g., lime) and sodium carbonate (e.g., soda), but also magnesium, calcium, manganese, aluminum, lead, boron, iron, chromium, potassium, sulfur and antimony, and carbonates and/or oxides of these elements and other elements. Meanwhile, the glass layer 111 may be distinguished from an organic insulating material including glass fiber (Glass Fiber, Glass Cloth or Glass Fabric), such as Copper Clad Laminate (CCL), Prepreg (PPG), or the like. The glass layer 111 may be in the form of, for example, a glass plate.

Each of the first to third insulating layers 112a, 112b and 112c and the first and second build-up insulating layers 113 and 114 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together with the resin. For example, the organic insulating material may include Prepreg (PPG), Ajinomoto Build-up Film (ABF), Photoimageable Dielectric (PID) and Bonding Sheet (BS), but the present is not limited thereto. The first to third insulating layers 112a, 112b and 112c may include substantially the same material, but the present disclosure is not limited thereto, and the first to third insulating layers 112a, 112b and 112c may include different materials. The first and second build-up insulation layers 113 and 114 may include substantially the same material, but the present disclosure is not limited thereto, and the first and second build-up insulation layers 113 and 114 may include different materials. The first and second build-up insulation layers 113 and 114 may be formed in a greater number of layers than those illustrated in the drawing, and, if necessary, one of the first and second build-up insulation layers 113 and 114 may be omitted.

Each of the first and second wiring layers 121 and 122 and the first and second build-up wiring layers 123 and 124 may include a metal. The metal may include copper (Cu), aluminum (Al), silver (Ag), tin (Sn), gold (Au), nickel (Ni), lead (Pb), titanium (Ti), and/or alloys thereof. For example, each of the first and second wiring layers 121 and 122 and the first and second build-up wiring layers 123 and 124 may include chemical copper formed by electroless plating, as a seed layer s2, and may include electrolytic copper formed by electrolytic plating, as a pattern plating layer m2 based thereon. Each of the first and second wiring layers 121 and 122 and the first and second build-up wiring layers 123 and 124 may perform various functions according to the design. For example, the first and second wiring layers 121 and 122 and the first and second build-up wiring layers 123 and 124 may include a signal pattern, a power pattern, and a ground pattern. These patterns may each have various forms such as a line, a trace, a plane, and a pad. The pad may be a concept including a land. The first and second build-up wiring layers 123 and 124 may be formed with a greater number of layers than those illustrated in the drawing, and, if necessary, one of the first and second build-up wiring layers 123 and 124 may be omitted.

The metal via 131 may include a metal. The metal may include copper (Cu), aluminum (Al), silver (Ag), tin (Sn), gold (Au), nickel (Ni), lead (Pb), titanium (Ti), and/or alloys thereof. For example, the metal via 131 may include a stack structure of a titanium layer and a copper layer formed by sputtering and/or electroless plating, as the seed layers s1-1 and s1-2. For example, the metal via 131 may include sputtered titanium and sputtered copper, sputtered titanium and chemical copper, or sputtered titanium, sputtered copper, and chemical copper. Additionally, a copper layer formed by electrolytic plating based thereon may be included as the plating layer m1. For example, the metal via 131 may include electrolytic copper. The metal via 131 may perform various functions depending on the design. For example, the metal via 131 may include a signal via, a power via, and a ground via. The metal via 131 may have a shape in which a side surface thereof is tapered, for example, an hourglass shape, but is not limited thereto, and may have a cylindrical shape in which a side surface thereof is approximately vertical. The metal via 131 may be a plated Through-Glass Via (TGV). There may be a plurality of metal vias 131, and the plurality of metal vias 131 may be spaced apart from each other.

The metal layer 132 may include a metal. The metal may include copper (Cu), aluminum (Al), silver (Ag), tin (Sn), gold (Au), nickel (Ni), lead (Pb), titanium (Ti), and/or alloys thereof. For example, the metal layer 132 may include a stack structure of a titanium layer and a copper layer formed by sputtering and/or electroless plating, as the seed layers s1-1 and s1-2. For example, the metal layer 132 may include sputtered titanium and sputtered copper, sputtered titanium and chemical copper, or sputtered titanium, sputtered copper, and chemical copper. Additionally, a copper layer formed by electrolytic plating based thereon may be included as the plating layer m1. For example, the metal layer 132 may include electrolytic copper. The metal layer 132 may be disposed on a wall surface of the cavity h so as to continuously surround the side surface of the electronic component 150 in the form of a metal plate.

Each of the first and second via layers 133 and 134 and the first and second build-up via layers 135 and 136 may each include a metal. The metal of the via layers 133-136 may include copper (Cu), aluminum (Al), silver (Ag), tin (Sn), gold (Au), nickel (Ni), lead (Pb), titanium (Ti), and/or alloys thereof. For example, each of the first and second via layers 133 and 134 and the first and second build-up via layers 135 and 136 may include chemical copper formed by electroless plating, as a seed layer s2, and may include electrolytic copper formed by electrolytic plating based thereon, as a pattern plating layer m2. Each of the first and second via layers 133 and 134 and the first and second build-up via layers 135 and 136 may perform various functions according to the design. For example, the first and second via layers 133 and 134 and the first and second build-up via layers 135 and 136 may include a signal via, a power via, and a ground via. Each of the first and second via layers 133 and 134 and the first and second build-up via layers 135 and 136 may include a filled VIA in which a via hole is filled with the metal, but may also include a conformal VIA in which the metal is disposed along the wall surface of the via hole. Each of the first and second via layers 133 and 134 and the first and second build-up via layers 135 and 136 may have a tapered shape. Each of the first and second via layers 133 and 134 and the first and second build-up via layers 135 and 136 may include a plurality of connecting vias. For example, the first via layer 133 may include a first connection via connecting at least a portion of the first wiring layer 121 to an upper surface of the metal via 131 and a second connection via connecting at least another portion of the first wiring layer 121 to the electronic component 150. The second via layer 134 may include a third connection via connecting at least a portion of the second wiring layer 122 to the lower surface of the metal via 131. The first and second build-up via layers 135 and 136 may be formed in a greater number of layers than those illustrated in the drawing, and, if necessary, one of the first and second build-up via layers 135 and 136 may be omitted.

The electronic component 150 may be various types of active components and/or passive components. For example, the electronic component 150 may include an Integrated Circuit Device (ICD) and an Embedded Passive Integrated Component (EPIC), but the present disclosure is not limited thereto. The electronic component 150 may be disposed in a cavity h of a glass layer 111 and may be embedded in a board. The electronic component 150 may be electrically connected to the first wiring layer 121 through the second connection via of the first via layer 133. The electronic component 150 may include a connection pad or a connection bump in contact with the second connection via of the first via layer 133.

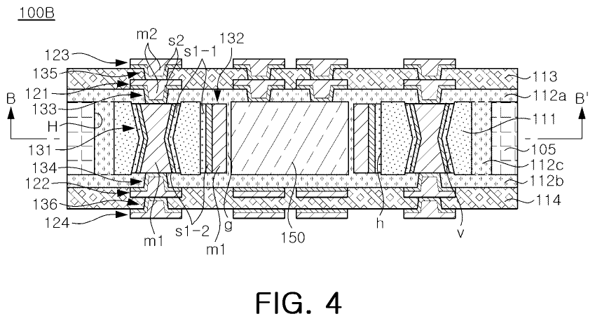

FIG. 4 is a cross-sectional view schematically illustrating another example of a printed circuit board.

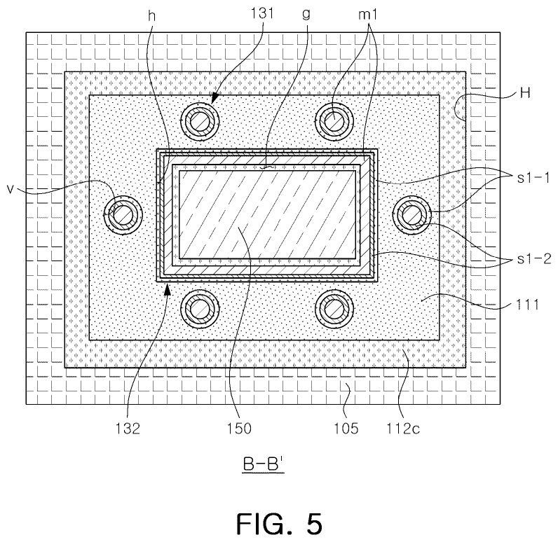

FIG. 5 is a schematic cut plan view taken along line B-B′ of the printed circuit board of FIG. 4.

Referring to the drawings, a printed circuit board 100B according to another example embodiment may be configured so that upper surfaces of each of a metal via 131 and a metal layer 132 may be disposed below an upper surface of a glass layer 111, and lower surfaces of each of the metal via 131 and the metal layer 132 may be disposed above the upper surface of the glass layer 111, in the printed circuit board 100A according to the above-described example. For example, in another example, the upper surface and the lower surface of the metal via 131 and the upper surface and the lower surface of the metal layer 132 may have a step portion from the upper surface and the lower surface of the glass layer 111, respectively. For example, in the process described below, the upper surfaces and the lower surfaces of each of the metal via 131 and the metal layer 132 may be partially removed during a flattening process using chemical mechanical polishing (CMP), or the like, so that the metal via 131 and the metal layer 132 may have a step portion from with the upper surface and the lower surface of the glass layer 111.

Other descriptions may be substantially the same as those described in the printed circuit board 100A according to the above-described example embodiment, and the technical effects may also be substantially the same.

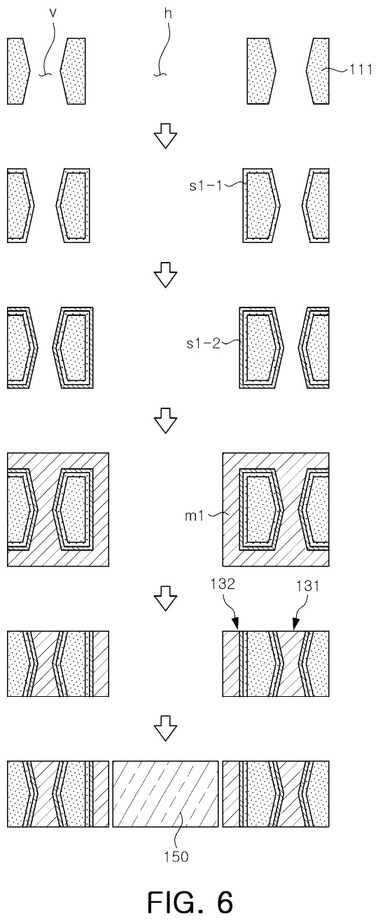

FIG. 6 is process cross-sectional views schematically illustrating a process of forming a through-hole and a cavity in a glass layer, forming a metal via and a metal layer in the through-hole and on a wall surface of the cavity, and disposing an electronic component in the cavity formed on the metal layer.

Referring to FIG. 6, first, a through-hole v and a cavity h may be formed in a glass layer 111. The through-hole v and the cavity h may be formed in a processing process using etching, blasting, laser, plasma, or the like. Next, a first seed layer s1-1 may be formed on an upper surface and a lower surface of the glass layer 111, a wall surface of the through-hole v and a wall surface of the cavity h by sputtering. Next, a second seed layer s1-2 may be formed on the first seed layer s1-1 by sputtering and/or electroless plating. The second seed layer s1-2 may be a single layer formed by sputtering, or a plurality of layers formed by chemical plating after sputtering. Next, a plating layer m1 may be formed on the second seed layer s1-2 by electrolytic plating. The plating layer m1 may fill an interior of the through-hole v. Next, the first and second seed layers s1-1 and s1-2 and the plating layer m1 disposed on the upper surface and the lower surface of the glass layer 111 may be removed in a planarization process using chemical mechanical polishing (CMP) or the like. In this case, the CMP process conditions may be optimized so that a wet etching process may be omitted. Accordingly, a metal via 131 may be formed in the through-hole v, and a metal layer 132 may be formed on the wall surface of the cavity h. Meanwhile, during the planarization process, the upper surfaces and the lower surfaces of each of the glass layer 111, the metal via 131 and the metal layer 132 may be coplanar with each other (for example, a printed circuit board structure according to an example embodiment). However, the present disclosure is not limited thereto, and the upper surfaces and the lower surfaces of the metal via 131 and the metal layer 132 may be partially removed to have a step portion from the upper surface and the lower surface of the glass layer 111, respectively (for example, a printed circuit board structure according to another example embodiment). Next, an electronic component 150 may be embedded in the cavity h. In this case, glass cracks occurring when the electronic component 150 collides with the glass layer 111 through the metal layer 132 may be prevented. Additionally, a build-up process may be performed thereafter, and the tensile stress may be reduced through the metal layer 132 to prevent glass cracks.

Other explanations may be substantially the same as those described in the printed circuit board 100A according to the example embodiment and the printed circuit board 100B according to another example embodiment, as described above.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component. For example, exposing a pad by an opening may mean exposing the pad from a resist layer, and a surface treatment layer or the like may be further disposed on the exposed pad.

In the present disclosure, being disposing in a through-portion or a through-hole may include not only a case in which an object is disposed completely in the through-portion or the through-hole, but also a case in which the object protrudes upwardly or downwardly in a cross-section. For example, when the object is placed in the through-portion or the through-hole in a plane, this may be determined in a broader sense.

In the present disclosure, determination may be performed by including process errors, positional deviations, errors at the time of measurement, which may occur substantially in a manufacturing process. For example, being substantially coplanar may include not only a complete coplanar case, but also an approximately coplanar case. In addition, being disposed on substantially the same level may include being disposed on approximately the same level as well as being disposed on completely the same level. In addition, having a substantially specific shape may include not only having a completely such shape, but also a case having approximately such a shape. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer;
a cavity penetrating between an upper surface and a lower surface of the glass layer;
a metal layer disposed on a wall surface of the cavity; and
an electronic component at least partially disposed in the cavity and spaced apart from the metal layer,
wherein an upper surface of the metal layer is disposed on substantially the same level as the upper surface of the glass layer, or is disposed below the upper surface of the glass layer, and
a lower surface of the metal layer is disposed on substantially the same level as the lower surface of the glass layer, or is disposed above the lower surface of the glass layer.

2. The printed circuit board according to claim 1, wherein the upper surface of the metal layer is substantially coplanar with the upper surface of the glass layer, and
the lower surface of the metal layer is substantially coplanar with the lower surface of the glass layer.

3. The printed circuit board according to claim 1, wherein the upper surface of the metal layer has a step portion from the upper surface of the glass layer, and
the lower surface of the metal layer has a step portion from the lower surface of the glass layer.

4. The printed circuit board according to claim 1, wherein the cavity continuously surrounds a side surface of the electronic component, and
the metal layer is disposed on the wall surface of the cavity in a form of a metal plate so as to continuously surround the side surface of the electronic component.

5. The printed circuit board according to claim 1, wherein the metal layer includes a first metal layer disposed on the wall surface of the cavity and a second metal layer disposed on the first metal layer,
wherein the first metal layer includes a stack structure of a titanium layer and a copper layer, and
the second metal layer includes a copper layer.

6. The printed circuit board according to claim 1, further comprising:
a through-hole penetrating between the upper surface and the lower surface of the glass layer; and
a metal via filling at least a portion of the through-hole;
wherein an upper surface of the metal via is disposed on substantially the same level as the upper surface of the glass layer or is disposed below the upper surface of the glass layer, and
a lower surface of the metal via is disposed on substantially the same level as the lower surface of the glass layer or is disposed above the lower surface of the glass layer.

7. The printed circuit board according to claim 6,
wherein the metal via includes a first metal layer disposed on a wall surface of the through-hole and a second metal layer disposed on the first metal layer and filling at least the portion of the through-hole,
the first metal layer includes a stack structure of a titanium layer and a copper layer, and
the second metal layer includes a copper layer.

8. The printed circuit board according to claim 6, further comprising:
a frame having a through-portion on which at least a portion of the glass layer is disposed;
a first insulating layer disposed on upper surfaces of each of the frame and the glass layer;
a first wiring layer disposed on an upper surface of the first insulating layer;
a first connection via penetrating through the first insulating layer and connecting at least a portion of the first wiring layer to the metal via;
a second connection via penetrating through the first insulating layer and connecting at least another portion of the first wiring layer to the electronic component;
a second insulation layer disposed on lower surfaces of each of the frame and the glass layer;
a second wiring layer disposed on a lower surface of the second insulation layer;
a third connection via penetrating through the second insulating layer and connecting at least a portion of the second wiring layer to the metal via; and
a third insulation layer filling at least a portion of a space between the frame and the glass layer in the through-portion,
wherein the first and third connection vias are in contact with the upper surface and the lower surface of the metal via, respectively.

9. The printed circuit board according to claim 8,
wherein the third insulation layer has an interlayer boundary with each of the first and second insulation layers.

10. The printed circuit board according to claim 8,
wherein the third insulating layer is integrated with one or more of the first and second insulating layers.

11. The printed circuit board according to claim 8, further comprising:
a first build-up insulating layer disposed on the upper surface of the first insulating layer;
a first build-up wiring layer disposed on an upper surface of the first build-up insulating layer;
a first build-up via layer penetrating through the first build-up insulating layer and connecting the first build-up insulating layer and the first wiring layer;
a second build-up insulating layer disposed on the lower surface of the second insulating layer;
a second build-up wiring layer disposed on a lower surface of the second build-up insulating layer; and
a second build-up via layer penetrating through the second build-up insulating layer and connecting the second build-up wiring layer and the second wiring layer.

12. A printed circuit board, comprising:
a glass layer;
a cavity penetrating through at least a portion of a space between an upper surface and a lower surface of the glass layer;
a metal layer disposed on a wall surface of the cavity; and
an electronic component at least partially disposed in the cavity and spaced apart from the metal layer,
wherein the metal layer includes a first metal layer disposed on the wall surface of the cavity and a second metal layer disposed on the first metal layer,
wherein the first metal layer includes a stack structure of a titanium layer and a copper layer, and
the second metal layer includes a copper layer.

13. The printed circuit board according to claim 12,
wherein, in a direction, substantially perpendicular to the wall surface of the cavity,
a thickness of the second metal layer is greater than a thickness of the first metal layer.

14. The printed circuit board according to claim 12, further comprising:
a through-hole penetrating between the upper surface and the lower surface of the glass layer; and
a metal via filling at least a portion of the through-hole,
wherein the metal via includes the first and second metal layers,
the first metal layer included in the metal via is disposed on a wall surface of the through-hole, and
the second metal layer included in the metal via is disposed on the first metal layer included in the metal via to further fill at least the portion of the through-hole.

15. The printed circuit board according to claim 14,
wherein the titanium layer of the first metal layer includes sputtered titanium,
the copper layer of the first metal layer includes at least one of sputtered copper or chemical copper, and
the copper layer of the second metal layer includes electrolytic copper.

16. The printed circuit board according to claim 12,
wherein the metal layer does not extend onto the upper and lower surfaces of the glass layer.
